(19) United States
(12) Patent Application Publication
(10) Pub. No.: US 2026/0293478 A1
(43) Pub. Date: Sep. 24, 2026

(54) DISPLAY DEVICE AND ELECTRONIC DEVICE

(71) Applicant: Samsung Display Co., Ltd., Yongin-si (KR)

(72) Inventor: Chun Gi YOU, Yongin-si (KR)

(21) Appl. No.: 19/375,758

(22) Filed: Oct. 31, 2025

(30) Foreign Application Priority Data
Mar. 18, 2025 (KR) 10-2025-0034568

(51) Int. Cl. H10K 59/131; H10K 59/122; H10K 59/88

(52) U.S. Cl. CPC H10K 59/1315; H10K 59/122; H10K 59/88

(57) ABSTRACT

A display device includes: a substrate including a display area and a non-display area; a first electrode in a sub-pixel area of the display area; a middle layer on the first electrode and defining a light emitting area of the first electrode; a light emitting stack on the middle layer; a second electrode on the light emitting stack; and a Test Element Group (TEG) layer in a power connection area of the non-display area and including a same material as the light emitting stack.

### CROSS-REFERENCE TO RELATED APPLICATION

The present application claims priority to and the benefit of Korean Patent Application No. 10-2025-0034568, filed on Mar. 18, 2025, in the Korean Intellectual Property Office, the entire disclosure of which is incorporated herein by reference.

### BACKGROUND

### 1. Field

Aspects of some embodiments of the present disclosure relate to a display device and an electronic device including the same.

### 2. Description of the Related Art

An organic light emitting display device includes a display element whose luminance may be changed according to a current applied to the display element. The display element may be, for example, an organic light emitting diode.

A head mounted display (HMD) to which the organic light emitting display device is applied is an image display device that may be worn on a user’s head in the form of glasses or a helmet and focuses on a distance close to the user’s eyes. The head mounted display may enable virtual reality (VR) or augmented reality (AR) applications.

The head mounted display may enlarge and display images displayed on a small display device using a plurality of lenses. Therefore, a display device applied to the head mounted display may desirably provide a high-resolution image, for example, an image having a resolution of 3000 pixels per inch (PPI) or higher. To this end, organic light emitting diode on silicon (OLEDoS), which is a high-resolution small-sized organic light emitting display device, may be used as the display device applied to the head mounted display. The OLEDoS is a device that displays images by arranging an organic light emitting diode (OLED) on a semiconductor wafer substrate on which a complementary metal oxide semiconductor (CMOS) is located.

The above information disclosed in this Background section is only for enhancement of understanding of the background and therefore the information discussed in this Background section does not necessarily constitute prior art.

### SUMMARY

Aspects of some embodiments of the present disclosure relate to a display device and an electronic device including the same, and for example, to a display device and an electronic device in which a thickness of a light emitting stack may be relatively accurately measured.

Aspects of some embodiments of the present disclosure include a display device and an electronic device in which a thickness of a light emitting stack may be relatively accurately measured.

According to some embodiments of the present disclosure, a display device includes: a substrate including a display area and a non-display area; a first electrode in a sub-pixel area of the display area; a middle layer on the first electrode and defining a light emitting area of the first electrode; a light emitting stack on the middle layer; a second electrode on the light emitting stack; and a Test Element Group (TEG) layer in a power connection area of the non-display area and including the same material as the light emitting stack.

According to some embodiments of the present disclosure, an electronic device includes: a display device providing a screen, wherein the display device includes: a substrate including a display area and a non-display area; a first electrode in a sub-pixel area of the display area; a middle layer on the first electrode and defining a light emitting area of the first electrode; a light emitting stack on the middle layer; a second electrode on the light emitting stack; and a Test Element Group (TEG) layer in a power connection area of the non-display area and including the same material as the light emitting stack.

According to some embodiments, the thickness of the light emitting stack may be relatively accurately measured.

For example, according to some embodiments, because the TEG layer may be formed in the guaranteed area (e.g., the power connection area), the quality of the TEG layer (e.g., the thickness of the TEG layer) may be guaranteed. Therefore, the thickness of the TEG layer in the power connection area may be the same (or substantially the same) as the thickness of the light emitting stack in the light emitting area, and thus the thickness of the TEG layer may relatively accurately reflect the thickness of the light emitting stack. Therefore, according to some embodiments, whether the thickness of the light emitting stack is defective may be relatively accurately determined.

The characteristics of embodiments according to the present disclosure are not limited to the above-described characteristics and other characteristics which are not described herein will become more apparent to those skilled in the art from the following description.

### BRIEF DESCRIPTION OF THE DRAWINGS

The above and other aspects and characteristics of embodiments according to the present disclosure will become more apparent by describing in more detail aspects of some embodiments thereof with reference to the attached drawings, in which:

FIG. 1 is an exploded perspective view illustrating a display device according to some embodiments;

FIG. 2 is a block diagram illustrating the display device according to some embodiments;

FIG. 3 is a layout view illustrating an example of a display panel according to some embodiments;

FIG. 4 is a layout view illustrating an example of a display area of FIG. 3;

FIG. 5 is a cross-sectional view illustrating an example of the display panel taken along the line I1-I1’ of FIG. 4;

FIG. 6 is a cross-sectional view illustrating further details of the area A1 of FIG. 7 in more detail;

FIG. 7 is a cross-sectional view illustrating further details of the area A2 of FIG. 6 in more detail;

FIG. 8 is an enlarged view of the area A3 of FIG. 3;

FIG. 9 is a cross-sectional view illustrating an example of the display panel taken along the line I2-I2’ of FIG. 8;

FIG. 10 is a block diagram of an electronic device according to some embodiments; and

FIGS. 11, 12 and 13 are schematic diagrams of electronic devices according to some embodiments.

### DETAILED DESCRIPTION

Aspects of some embodiments of the present disclosure will now be described more fully hereinafter with reference to the accompanying drawings, in which aspects of some embodiments according to the present disclosure are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being "on" another layer or substrate, it can be directly on the other layer or substrate, or intervening layers may also be present. The same reference numbers indicate the same components throughout the specification. In the attached figures, the thickness of layers and regions is exaggerated for clarity.

Although the terms "first", "second", etc. may be used herein to describe various elements, these elements, should not be limited by these terms. These terms may be used to distinguish one element from another element. Thus, a first element discussed below may be termed a second element without departing from teachings of one or more embodiments. The description of an element as a "first" element may not require or imply the presence of a second element or other elements. The terms "first", "second", etc. may also be used herein to differentiate different categories or sets of elements. For conciseness, the terms "first", "second", etc. may represent "first-category (or first-set)", "second-category (or second-set)", etc., respectively.

Features of various embodiments of the present disclosure may be combined partially or totally. As will be clearly appreciated by those skilled in the art, technically various interactions and operations are possible. Various embodiments can be practiced individually or in combination.

Hereinafter, aspects of some embodiments will be described in more detail with reference to the accompanying drawings.

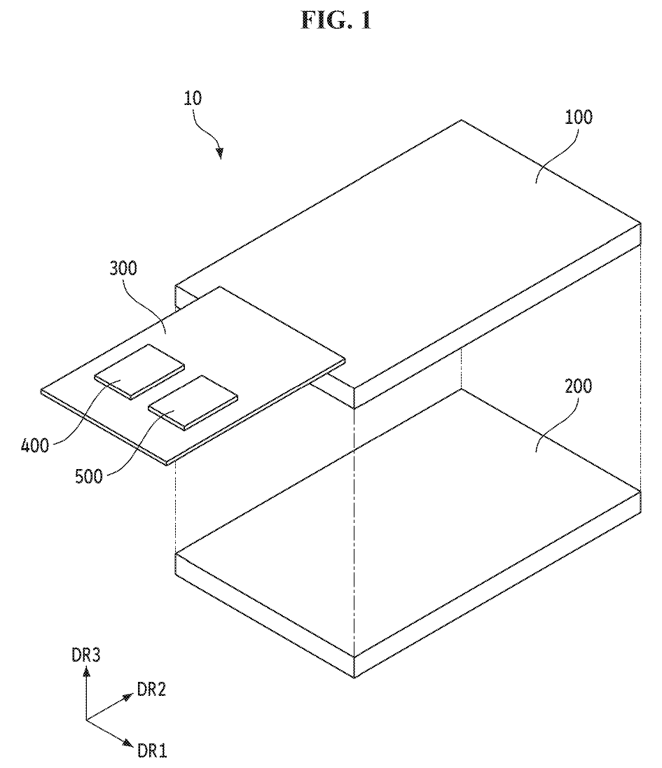

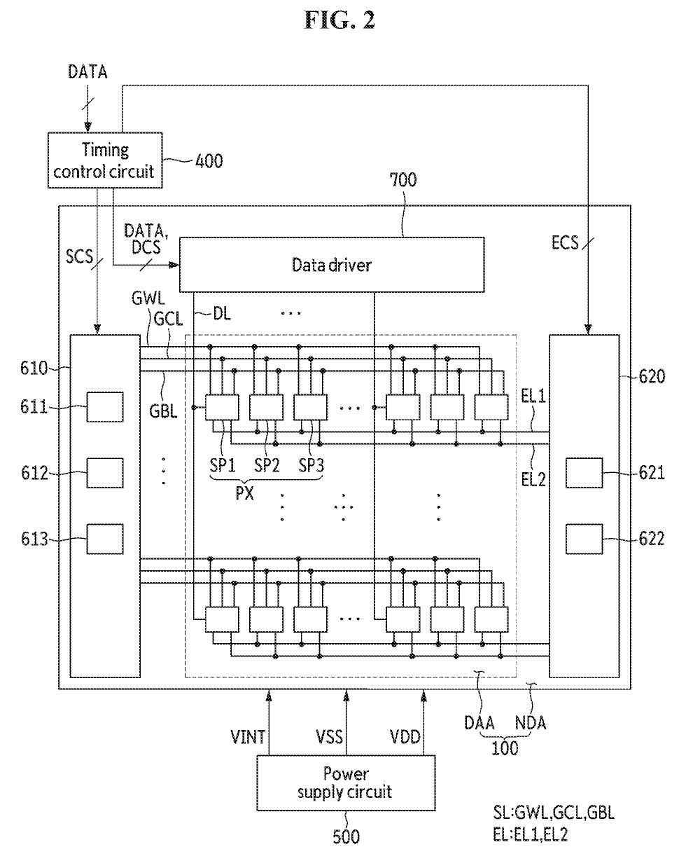

FIG. 1 is an exploded perspective view illustrating a display device according to some embodiments. FIG. 2 is a block diagram illustrating the display device according to some embodiments.

Referring to FIGS. 1 and 2, a display device 10 according to some embodiments is a device configured to display moving images (e.g., video images) or still images (e.g., static images). The display device 10 according to some embodiments may be applied to portable electronic devices such as a mobile phone, a smart phone, a tablet personal computer (PC), a mobile communication terminal, an electronic notebook, an electronic book, a portable multimedia player (PMP), navigation, and an ultra mobile PC (UMPC). For example, the display device 10 according to some embodiments may be applied to a display unit of a television, a laptop computer, a monitor, a billboard, or the Internet of Things (IoT). Alternatively, the display device 10 according to some embodiments may be applied to a smart watch, a watch phone, and a head mounted display (HMD) for implementing virtual reality and augmented reality.

The display device 10 according to some embodiments may have a resolution of, for example, 4,000 pixels per inch (PPI) or more.

The display device 10 according to some embodiments includes a display panel 100, a heat dissipation layer 200, a circuit board 300, a timing control circuit 400, and a power supply circuit 500.

The display panel 100 may be formed in a planar shape similar to a quadrangle. For example, the display panel 100 may have a planar shape similar to a quadrangle having short sides in a first direction DR1 and long sides in a second direction DR2 intersecting the first direction DR1. In the display panel 100, a corner where the short side in the first direction DR1 and the long side in the second direction DR2 meet may be rounded to have a curvature or may be formed at a right angle. The planar shape of the display panel 100 is not limited to the quadrangle, and may be formed similarly to other polygons, circles, ovals, or irregular shapes in a plan view. A planar shape of the display device 10 may follow the planar shape of the display panel 100, but the embodiments of the present disclosure are not limited thereto.

The display panel 100 includes a plurality of pixels PX, a plurality of scan lines SL, a plurality of emission control lines EL, a plurality of data lines DL, a scan driver 610, a light emitting driver 620, and a data driver 700. The display panel 100 may be divided into a display area DAA displaying images and a non-display area NDA that does not display images, as illustrated in FIG. 2. According to some embodiments, the non-display area NDA may surround (e.g., in a periphery or outside a footprint of) the display area DAA.

The plurality of pixels PX may be located in the display area DAA. The plurality of pixels PX may be arranged in a matrix form in the first direction DR1 and the second direction DR2. The plurality of scan lines SL and the plurality of emission control lines EL may extend in the first direction DR1 and may be arranged in the second direction DR2. The plurality of data lines DL may extend in the second direction DR2 and may be arranged in the first direction DR1.

The plurality of scan lines SL includes a plurality of write scan lines GWL, a plurality of control scan lines GCL, and a plurality of bias scan lines GBL. The plurality of emission control lines EL include a plurality of first emission control lines EL1 and a plurality of second emission control lines EL2.

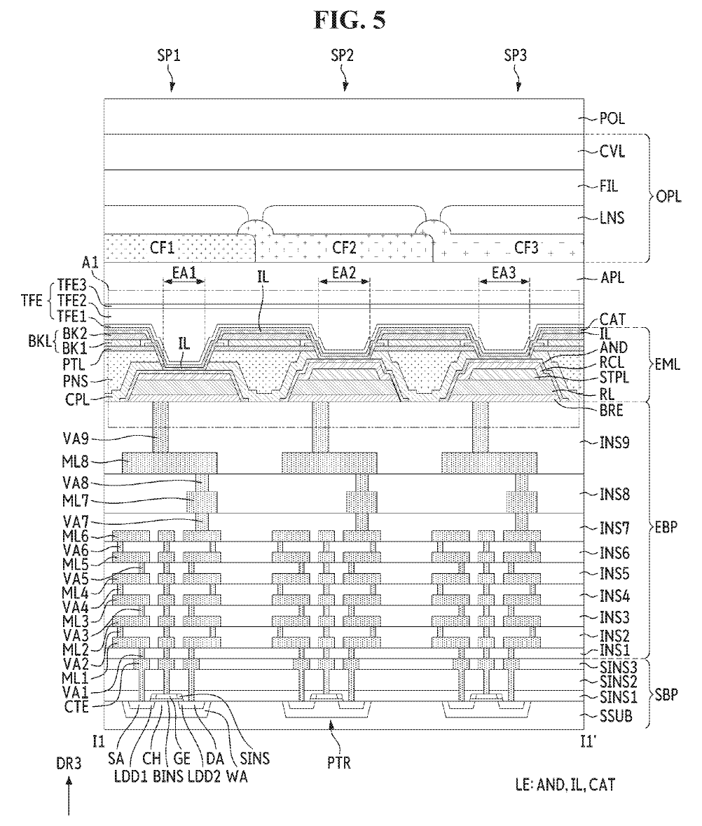

The plurality of pixels PX include a plurality of sub-pixel areas SP1, SP2, and SP3. The plurality of sub-pixel areas SP1, SP2, and SP3 may include a plurality of pixel transistors, and the plurality of pixel transistors may be formed through a semiconductor process and may be located on a semiconductor substrate (e.g., SSUB in FIG. 5). For example, the plurality of pixel transistors may be formed of a Complementary Metal Oxide Semiconductor (CMOS), but the embodiments of the present disclosure are not limited thereto.

Each of the plurality of sub-pixel areas SP1, SP2, and SP3 may be connected to any one write scan line GWL among the plurality of write scan lines GWL, any one control scan line GCL among the plurality of control scan lines GCL, any one bias scan line GBL among the plurality of bias scan lines GBL, any one first emission control line EL1 among the plurality of first emission control lines EL1, any one second emission control line EL2 among the plurality of second emission control lines EL2, and any one data line DL among the plurality of data lines DL. Each of the plurality of sub-pixel areas SP1, SP2, and SP3 may receive a data voltage of the data line DL according to a write scan signal of the write scan line GWL, and may emit light from a light emitting element according to the data voltage.

The scan driver 610, the light emitting driver 620, and the data driver 700 may be located in the non-display area NDA.

The scan driver 610 includes a plurality of scan transistors, and the light emitting driver 620 includes a plurality of light emitting transistors. The plurality of scan transistors and the plurality of light emitting transistors may be formed through a semiconductor process and may be formed on a semiconductor substrate (SSUB in FIG. 7). For example, the plurality of scan transistors and the plurality of light emitting transistors may be formed of CMOS, but the embodiments of the present disclosure are not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and sequentially output the write scan signals to the write scan lines GWL. The control scan signal output unit 612 may generate control scan signals according to the scan timing control signal SCS and sequentially output the control scan signals to the control scan lines GCL. The bias scan signal output unit 613 may generate bias scan signals according to the scan timing control signal SCS and sequentially output the bias scan signals to the bias scan lines GBL.

The light emitting driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output the first emission control signals to the first emission control lines EL1. The second emission control driver 622 may generate second emission control signals according to the emission timing control signal ECS and sequentially output the second emission control signals to the second emission control lines EL2.

The data driver 700 may include a plurality of data transistors, and the plurality of data transistors may be formed through a semiconductor process and may be formed on a semiconductor substrate (SSUB in FIG. 7). For example, the plurality of data transistors may be formed of CMOS, but the embodiments of the present disclosure are not limited thereto.

The data driver 700 may receive digital video data DATA and a data timing control signal DCS from the timing control circuit 400. The data driver 700 converts the digital video data DATA into analog data voltages according to the data timing control signal DCS and outputs the converted analog data voltages to the data lines DL. In this case, the sub-pixel areas SP1, SP2, and SP3 may be selected by the write scan signals of the scan driver 610, and the data voltages may be supplied to the selected sub-pixel areas SP1, SP2, and SP3.

The heat dissipation layer 200 may overlap the display panel 100 in a third direction DR3, which is a thickness direction of the display panel 100. The heat dissipation layer 200 may be located on one surface of the display panel 100, for example, a rear surface of the display panel 100. The heat dissipation layer 200 serves to dissipate heat generated from the display panel 100. The heat dissipation layer 200 may include a metal layer such as graphite, silver (Ag), copper (Cu), or aluminum (Al) having high thermal conductivity.

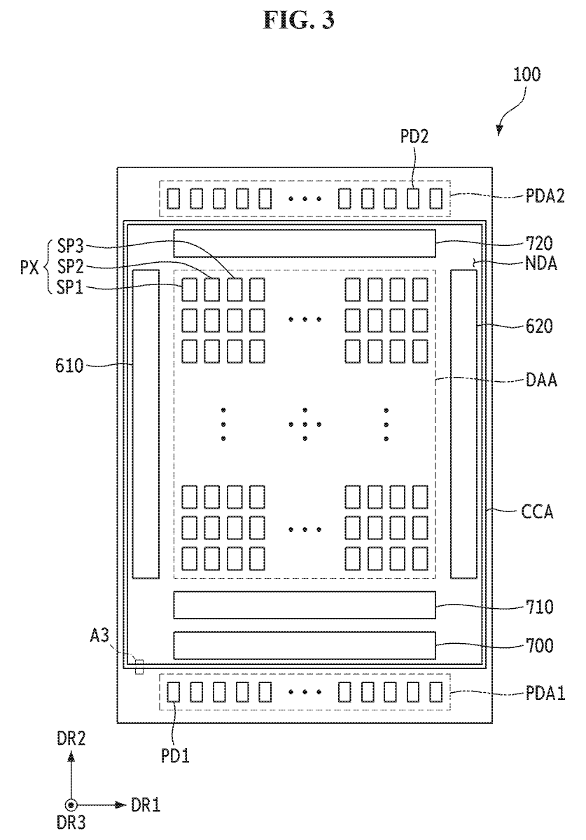

The circuit board 300 may be electrically connected to a plurality of first pads (PD1 in FIG. 3) of a first pad area (PDA1 in FIG. 3) of the display panel 100 by using a conductive adhesive member such as an anisotropic conductive film. The circuit board 300 may be a flexible printed circuit board or flexible film made of a flexible material. It is illustrated in FIG. 1 that the circuit board 300 is unfolded, but the circuit board 300 may be bent. In this case, one end of the circuit board 300 may be located on the rear surface of the display panel 100 and/or a rear surface of the heat dissipation layer 200. The other end of the circuit board 300 may be connected to the plurality of first pads (PD1 in FIG. 3) of the first pad area (PDA1 in FIG. 3) of the display panel 100 by using a conductive adhesive member. One end of the circuit board 300 may be an end opposite to the other end of the circuit board 300.

The timing control circuit 400 may receive digital video data and timing signals from the outside. The timing control circuit 400 may generate a scan timing control signal SCS, an emission timing control signal ECS, and a data timing control signal DCS for controlling the display panel 100 according to the timing signals. The timing control circuit 400 may output the scan timing control signal SCS to the scan driver 610 and output the emission timing control signal ECS to the light emitting driver 620. The timing control circuit 400 may output the digital video data and the data timing control signal DCS to the data driver 700.

The power supply circuit 500 may generate a plurality of panel driving voltages according to a power voltage from the outside. For example, the power supply circuit 500 may generate a first driving voltage VSS, a second driving voltage VDD, and a third driving voltage VINT and supply the generated driving voltages to the display panel 100.

Each of the timing control circuit 400 and the power supply circuit 500 may be formed as an integrated circuit (IC) and attached to one surface of the circuit board 300. In this case, the scan timing control signal SCS, the emission timing control signal ECS, the digital video data DATA, and the data timing control signal DCS of the timing control circuit 400 may be supplied to the display panel 100 through the circuit board 300. In addition, the first driving voltage VSS, the second driving voltage VDD, and the third driving voltage VINT of the power supply circuit 500 may be supplied to the display panel 100 through the circuit board 300.

Alternatively, each of the timing control circuit 400 and the power supply circuit 500 may be located in the non-display area NDA of the display panel 100, similarly to the scan driver 610, the light emitting driver 620, and the data driver 700. In this case, the timing control circuit 400 may include a plurality of timing transistors, and each power supply circuit 500 may include a plurality of power transistors. The plurality of timing transistors and the plurality of power transistors may be formed through a semiconductor process and may be formed on a semiconductor substrate (SSUB in FIG. 7). For example, the plurality of timing transistors and the plurality of power transistors may be formed of CMOS, but the embodiments of the present disclosure are not limited thereto. Each of the timing control circuit 400 and the power supply circuit 500 may be located between the data driver 700 and the first pad area (PDA1 in FIG. 3).

FIG. 3 is a layout view illustrating an example of a display panel according to some embodiments.

Referring to FIG. 3, the display area DAA of the display panel 100 according to some embodiments includes a plurality of pixels PX arranged in a matrix form or arrangement (e.g., of a plurality of rows and columns of pixels PX). The non-display area NDA of the display panel 100 according to some embodiments includes a scan driver 610, a light emitting driver 620, a data driver 700, a first distribution circuit 710, a second distribution circuit 720, a first pad portion PDA1, and a second pad portion PDA2.

The scan driver 610 may be located on a first side of the display area DAA, and the light emitting driver 620 may be located on a second side of the display area DAA. For example, the scan driver 610 may be located on one side of the display area DAA in the first direction DR1, and the light emitting driver 620 may be located on the other side of the display area DAA in the first direction DR1. That is, the scan driver 610 may be located on a left side of the display area DAA, and the light emitting driver 620 may be located on a right side of the display area DAA. However, the embodiments of the present disclosure are not limited thereto, and the scan driver 610 and the light emitting driver 620 may be located on both the first side and the second side of the display area DAA.

The first pad portion PDA1 may include a plurality of first pads PD1 connected to pads or bumps of the circuit board 300 through a conductive adhesive member. The first pad portion PDA1 may be located on a third side of the display area DAA. For example, the first pad portion PDA1 may be located on one side of the display area DAA in the second direction DR2. The first pad portion PDA1 may be located on the outside of the data driver 700 in the second direction DR2. That is, the first pad portion PDA1 may be located closer to an edge of the display panel 100 than the data driver 700.

The second pad portion PDA2 may include a plurality of second pads PD2 corresponding to test pads for testing whether the display panel 100 is normally operating. The plurality of second pads PD2 may be connected to a jig or probe pin or to a test circuit board during the test process. The test circuit board may be a printed circuit board made of a rigid material or a flexible printed circuit board made of a flexible material.

The second pad portion PDA2 may be located on a fourth side of the display area DAA. For example, the second pad portion PDA2 may be located on the other side of the display area DAA in the second direction DR2. The second pad portion PDA2 may be located on the outside of the second distribution circuit 720 in the second direction DR2. That is, the second pad portion PDA2 may be located closer to the edge of the display panel 100 than the second distribution circuit 720.

The first distribution circuit 710 distributes the data voltages applied through the first pad portion PDA1 to the plurality of data lines DL. For example, the first distribution circuit 710 may distribute data voltages applied through one first pad PD1 of the first pad portion PDA1 to P (P is a positive integer greater than or equal to 2) data lines DL, thereby reducing the number of first pads PD1. The first distribution circuit 710 may be located on a third side of the display area DAA of the display panel 100. For example, the first distribution circuit 710 may be located on one side of the display area DAA in the second direction DR2. That is, the first distribution circuit 710 may be located on a lower side of the display area DAA.

The second distribution circuit 720 distributes signals applied through the second pad portion PDA2 to the scan driver 610, the light emitting driver 620, and the data lines DL. The second pad portion PDA2 and the second distribution circuit 720 may be components for testing the operation of each pixel PX of the display area DAA. The second distribution circuit 720 may be located on a fourth side of the display area DAA of the display panel 100. For example, the second distribution circuit 720 may be located on the other side of the display area DAA in the second direction DR2. That is, the second distribution circuit 720 may be located on an upper side of the display area DAA.

The display device 10 may include an active area that implements or displays images and a non-active area that is located outside (e.g., in a periphery or outside a footprint of) the active area and does not implement or display images. Here, a maximum width (e.g., a widest width) of the active area may be, for example, 1.5 inches or less. Here, maximum width may refer to the longest measurable transverse length in the active area. For example, when the display device 10 has a quadrangular shape, the maximum width described above may correspond to a diagonal length of the display device 10.

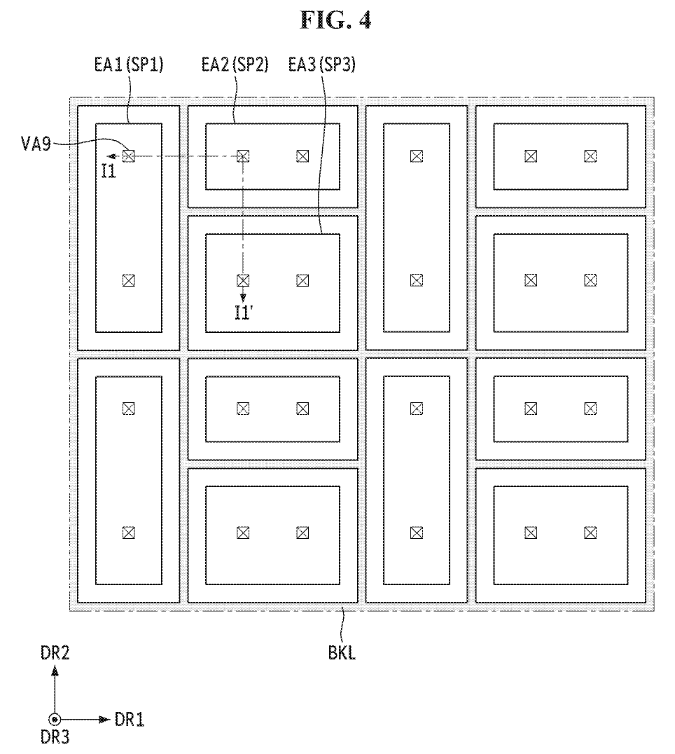

FIG. 4 is a layout view illustrating an example of a display area of FIG. 3.

Referring to FIG. 4, each of the plurality of pixels PX includes a first light emitting area EA1, which is a light emitting area of the first sub-pixel area SP1, a second light emitting area EA2, which is a light emitting area of the second sub-pixel area SP2, and a third light emitting area EA3, which is a light emitting area of the third sub-pixel area SP3.

Each of the first light emitting area EA1, the second light emitting area EA2, and the third light emitting area EA3 may have a polygonal, circular, elliptical, or irregular planar shape (e.g., in a plan view).

A maximum length (e.g., a longest length) of the first light emitting area EA1 in the first direction DR1 may be smaller than a maximum length of the second light emitting area EA2 in the first direction DR1 and a maximum length of the third light emitting area EA3 in the first direction DR1. The maximum length of the second light emitting area EA2 in the first direction DR1 and the maximum length of the third light emitting area EA3 in the first direction DR1 may be the same (or substantially the same).

A maximum length of the first light emitting area EA1 in the second direction DR2 may be longer than a maximum length of the second light emitting area EA2 in the second direction DR2 and a maximum length of the third light emitting area EA3 in the second direction DR2. The maximum length of the second light emitting area EA2 in the second direction DR2 may be longer than the maximum length of the third light emitting area EA3 in the second direction DR2. The maximum length of the first light emitting area EA1 in the second direction DR2 may be smaller than the maximum length of the second light emitting area EA2 in the second direction DR2.

The first light emitting area EA1, the second light emitting area EA2, and the third light emitting area EA3 may have a polygonal, circular, elliptical, or irregular planar shape other than a quadrangle.

As illustrated in FIG. 4, in each of the plurality of pixels PX, the first light emitting area EA1 and the second light emitting area EA2 may be adjacent to each other in the first direction DR1. In addition, the first light emitting area EA1 and the third light emitting area EA3 may be adjacent to each other in the first direction DR1. In addition, the second light emitting area EA2 and the third light emitting area EA3 may be adjacent to each other in the second direction DR2. An area of the first light emitting area EA1, an area of the second light emitting area EA2, and an area of the third light emitting area EA3 may be different.

The first sub-pixel area SP1 may emit first light that has passed through a first color filter (CF1 in FIG. 7) among the light emitted from the first light emitting area EA1, the second sub-pixel area SP2 may emit second light that has passed through a second color filter (CF2 in FIG. 7) among the light emitted from the second light emitting area EA2, and the third sub-pixel area SP3 may emit first light that has passed through a third color filter (CF3 in FIG. 7) among the light emitted from the third light emitting area EA3.

The first light, the second light and the third light described above may be light in different wavelength bands. For example, one of the first to third lights may be light in a green wavelength band, another light may be light in a red wavelength band, and the remaining other light may be light in a blue wavelength band. Here, the blue wavelength band may indicate that a main peak wavelength of light is included in a wavelength band in a range of 370 nanometers (nm) to 460 nm (or approximately 370 nm to 460 nm), the green wavelength band may indicate that a main peak wavelength of light is included in a wavelength band of 480 nm to 560 nm (or approximately 480 nm to 560 nm), and the red wavelength band may indicate that a main peak wavelength of light is included in a wavelength band of 600 nm to 750 nm (or approximately 600 nm to 750 nm).

It is illustrated in FIG. 4 that each of the plurality of pixels PX includes the three light emitting areas EA1, EA2, and EA3, but the embodiments of the present disclosure are not limited thereto. That is, each of the plurality of pixels PX may also include four light emitting areas.

In addition, the arrangement of the light emitting areas of the plurality of pixels PX is not limited to that illustrated in FIG. 4. For example, the light emitting areas of the plurality of pixels PX may be arranged in a stripe structure in which the light emitting areas are arranged in the first direction DR1 and a PenTile® structure in which the light emitting areas have a diamond arrangement.

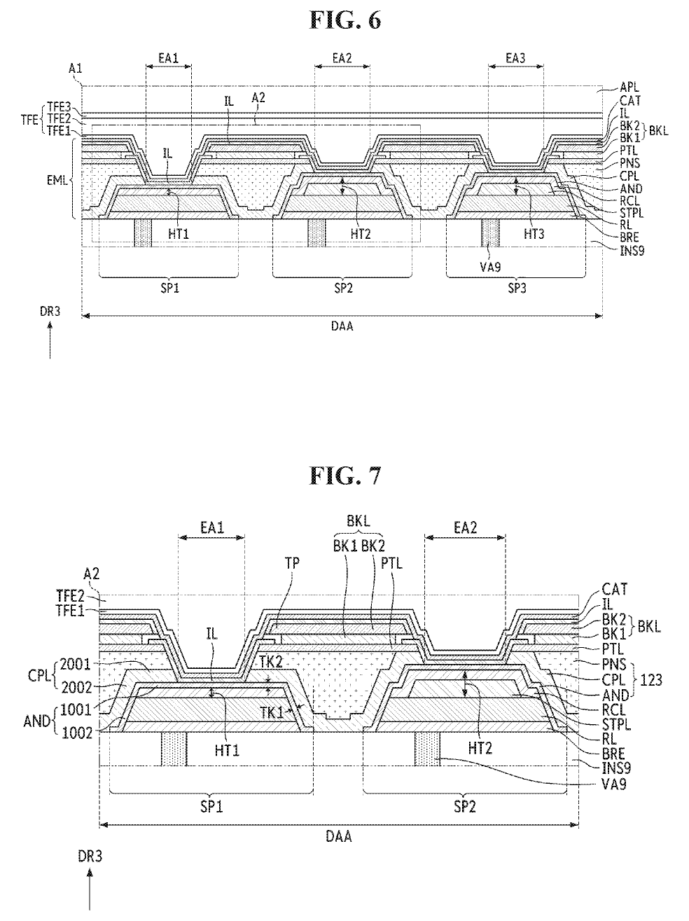

FIG. 5 is a cross-sectional view illustrating an example of the display panel taken along the line I1-I1’ of FIG. 4, FIG. 6 is a cross-sectional view illustrating area A1 of FIG. 5 in more detail, and FIG. 7 is a cross-sectional view illustrating area A2 of FIG. 6 in more detail.

Referring to FIGS. 5-7, the display panel 100 includes a semiconductor backplane SBP, a light emitting element backplane EBP, a display element layer EML, an encapsulation layer TFE, an optical layer OPL, a cover layer CVL, and a polarizing plate POL.

The semiconductor backplane SBP includes a semiconductor substrate SSUB including a plurality of pixel transistors PTR, a plurality of semiconductor insulating layers covering the plurality of pixel transistors PTR, and a plurality of contact terminals CTE electrically connected to the plurality of pixel transistors PTR, respectively.

The semiconductor substrate SSUB may be a silicon substrate, a germanium substrate, or a silicon-germanium substrate. The semiconductor substrate SSUB may be a substrate doped with first-type impurities. A plurality of well areas WA may be located at an upper surface of the semiconductor substrate SSUB. The plurality of well areas WA may be areas doped with second-type impurities. The second-type impurity may be different from the first-type impurity described above. For example, when the first-type impurity is a p-type impurity, the second-type impurity may be an n-type impurity. Alternatively, when the first-type impurity is an n-type impurity, the second-type impurity may be a p-type impurity.

Each of the plurality of well areas WA includes a source area SA corresponding to a source electrode of the pixel transistor PTR, a drain area DA corresponding to a drain electrode thereof, and a channel area CH located between the source area SA and the drain area DA.

A lower insulating layer BINS may be located between the gate electrode GE and the well area WA. A side insulating layer SINS may be located on a side surface of the gate electrode GE. The side insulating layer SINS may be located on the lower insulating layer BINS.

Each of the source area SA and the drain area DA may be an area doped with first-type impurities. The gate electrode GE of the pixel transistor PTR may overlap the well area WA in the third direction DR3, which is a thickness direction of the semiconductor substrate SSUB. The channel area CH may overlap the gate electrode GE in the third direction DR3. The source area SA may be located on one side of the gate electrode GE, and the drain area DA may be located on the other side of the gate electrode GE.

Each of the plurality of well areas WA further includes a first low-concentration impurity area LDD1 located between the channel area CH and the source area SA and a second low-concentration impurity area LDD2 located between the channel area CH and the drain area DA. The first low-concentration impurity area LDD1 may be an area having an impurity concentration lower than that of the source area SA due to the lower insulating layer BINS. The second low-concentration impurity area LDD2 may be an area having an impurity concentration lower than that of the drain area DA due to the lower insulating layer BINS. A distance between the source area SA and the drain area DA may be increased due to the first low-concentration impurity area LDD1 and the second low-concentration impurity area LDD2. Therefore, because a length of the channel area CH of each of the pixel transistors PTR may increase, punch-through and hot carrier phenomena caused by a short channel may be prevented or reduced.

A first semiconductor insulating layer SINS1 may be located on the semiconductor substrate SSUB. The first semiconductor insulating layer SINS1 may include a silicon nitride carbon (SiCN) or silicon oxide (SiOₓ)-based inorganic film, but the embodiments of the present disclosure are not limited thereto.

A second semiconductor insulating layer SINS2 may be located on the first semiconductor insulating layer SINS1. The second semiconductor insulating layer SINS2 may include a silicon oxide (SiOₓ)-based inorganic film, but the embodiments of the present disclosure are not limited thereto.

The plurality of contact terminals CTE may be located on the second semiconductor insulating layer SINS2. Each of the plurality of contact terminals CTE may be connected to any one of the gate electrode GE, the source area SA, and the drain area DA of each of the pixel transistors PTR through a hole penetrating through the first semiconductor insulating layer SINS1 and the second semiconductor insulating layer SINS2. The plurality of contact terminals CTE may include any one of copper (Cu), aluminum (Al), tungsten (W), molybdenum (Mo), chromium (Cr), gold (Au), titanium (Ti), nickel (Ni), and neodymium (Nd), or an alloy including any one thereof.

A third semiconductor insulating layer SINS3 may be located on a side surface of each of the plurality of contact terminals CTE. An upper surface of each of the plurality of contact terminals CTE may be exposed without being covered by the third semiconductor insulating layer SINS3. The third semiconductor insulating layer SINS3 may include a silicon oxide (SiOₓ)-based inorganic film, but the embodiments of the present disclosure are not limited thereto.

The semiconductor substrate SSUB may be replaced with a glass substrate or a polymer resin substrate such as polyimide. In this case, thin film transistors may be located on the glass substrate or the polymer resin substrate. The glass substrate may be a rigid substrate that is not bent, and the polymer resin substrate may be a flexible substrate that may be bent or curved.

The light emitting element backplane EBP includes a plurality of conductive layers ML1 to ML8, a plurality of via electrodes VA1 to VA9, and a plurality of insulating layers INS1 to INS11. In addition, the light emitting element backplane EBP includes a plurality of insulating layers INS1 to INS11 located between first to eighth conductive layers ML1 to ML8.

The first to eighth conductive layers ML1 to ML8 serve to implement the circuit of the first sub-pixel area SP1 illustrated in FIG. 4 by connecting the plurality of contact terminals CTE exposed from the semiconductor backplane SBP.

A first insulating layer INS1 may be located on the semiconductor backplane SBP. Each first via electrode VA1 may penetrate through the first insulating layer INS1 and be connected to the contact terminal CTE exposed from the semiconductor backplane SBP. Each of the first conductive layers ML1 may be located on the first insulating layer INS1 and may be connected to the first via electrode VA1.

A second insulating layer INS2 may be located on the first insulating layer INS1 and the first conductive layers ML1. Each second via electrode VA2 may be connected to the first conductive layer ML1 exposed by penetrating through the second insulating layer INS2. Each of the second conductive layers ML2 may be located on the second insulating layer INS2 and may be connected to the second via electrode VA2.

A third insulating layer INS3 may be located on the second insulating layer INS2 and the second conductive layers ML2. Each third via electrode VA3 may be connected to the second conductive layer ML2 exposed by penetrating through the third insulating layer INS3. Each of the third conductive layers ML3 may be located on the third insulating layer INS3 and may be connected to the third via electrode VA3.

A fourth insulating layer INS4 may be located on the third insulating layer INS3 and the third conductive layers ML3. Each fourth via electrode VA4 may be connected to the third conductive layer ML3 exposed by penetrating through the fourth insulating layer INS4. Each of the fourth conductive layers ML4 may be located on the fourth insulating layer INS4 and may be connected to the fourth via electrode VA4.

A fifth insulating layer INS5 may be located on the fourth insulating layer INS4 and the fourth conductive layers ML4. Each fifth via electrode VA5 may be connected to the fourth conductive layer ML4 exposed by penetrating through the fifth insulating layer INS5. Each of the fifth conductive layers ML5 may be located on the fifth insulating layer INS5 and may be connected to the fifth via electrode VA5.

A sixth insulating layer INS6 may be located on the fifth insulating layer INS5 and the fifth conductive layers ML5. Each sixth via electrode VA6 may be connected to the fifth conductive layer ML5 exposed by penetrating through the sixth insulating layer INS6. Each of the sixth conductive layers ML6 may be located on the sixth insulating layer INS6 and may be connected to the sixth via electrode VA6.

A seventh insulating layer INS7 may be located on the sixth insulating layer INS6 and the sixth conductive layers ML6. Each seventh via electrode VA7 may be connected to the sixth conductive layer ML6 exposed by penetrating through the seventh insulating layer INS7. Each of the seventh conductive layers ML7 may be located on the seventh insulating layer INS7 and may be connected to the seventh via electrode VA7.

An eighth insulating layer INS8 may be located on the seventh insulating layer INS7 and the seventh conductive layers ML7. Each eighth via electrode VA8 may be connected to the seventh conductive layer ML7 exposed by penetrating through the eighth insulating layer INS8. Each of the eighth conductive layers ML8 may be located on the eighth insulating layer INS8 and may be connected to the eighth via electrode VA8.

The first to eighth conductive layers ML1 to ML8 and the first to eighth via electrodes VA1 to VA8 may include the same (or substantially the same) material. The first to eighth conductive layers ML1 to ML8 and the first to eighth via electrodes VA1 to VA8 may include any one of copper (Cu), aluminum (Al), tungsten (W), molybdenum (Mo), chromium (Cr), gold (Au), titanium (Ti), nickel (Ni), and neodymium (Nd), or an alloy including any one thereof. The first to eighth via electrodes VA1 to VA8 may include the same (or substantially the same) material. The first to eighth insulating layers INS1 to INS8 may include a silicon oxide (SiOₓ)-based inorganic film, but the embodiments of the present disclosure are not limited thereto.

Each of a thickness of the first conductive layer ML1, a thickness of the second conductive layer ML2, a thickness of the third conductive layer ML3, a thickness of the fourth conductive layer ML4, a thickness of the fifth conductive layer ML5, and a thickness of the sixth conductive layer ML6 may be greater than each of a thickness of the first via electrode VA1, a thickness of the second via electrode VA2, a thickness of the third via electrode VA3, a thickness of the fourth via electrode VA4, a thickness of the fifth via electrode VA5, and a thickness of the sixth via electrode VA6. Each of the thickness of the second conductive layer ML2, the thickness of the third conductive layer ML3, the thickness of the fourth conductive layer ML4, the thickness of the fifth conductive layer ML5, and the thickness of the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be the same (or substantially the same). For example, the thickness of the first conductive layer ML1 may be 1,360 Å (or approximately 1,360 Å), each of the thickness of the second conductive layer ML2, the thickness of the third conductive layer ML3, the thickness of the fourth conductive layer ML4, the thickness of the fifth conductive layer ML5, and the thickness of the sixth conductive layer ML6 may be 1,440 Å (or approximately 1,440 Å), and each of the thickness of the first via electrode VA1, the thickness of the second via electrode VA2, the thickness of the third via electrode VA3, the thickness of the fourth via electrode VA4, the thickness of the fifth via electrode VA5, and the thickness of the sixth via electrode VA6 may be 1,150 Å (or approximately 1,150 Å).

Each of a thickness of the seventh conductive layer ML7 and a thickness of the eighth conductive layer ML8 may be greater than each of the thickness of the first conductive layer ML1, the thickness of the second conductive layer ML2, the thickness of the third conductive layer ML3, the thickness of the fourth conductive layer ML4,the thickness of the fifth conductive layer ML5, and the thickness of the sixth conductive layer ML6. Each of the thickness of the seventh conductive layer ML7 and the thickness of the eighth conductive layer ML8 may be greater than each of a thickness of the seventh via electrode VA7 and a thickness of the eighth via electrode VA8. Each of the thickness of the seventh via electrode VA7 and the thickness of the eighth via electrode VA8 may be greater than each of the thickness of the first via electrode VA1, the thickness of the second via electrode VA2, the thickness of the third via electrode VA3, the thickness of the fourth via electrode VA4, the thickness of the fifth via electrode VA5, and the thickness of the sixth via electrode VA6. The thickness of the seventh conductive layer ML7 and the thickness of the eighth conductive layer ML8 may be the same (or substantially the same). For example, each of the thickness of the seventh conductive layer ML7 and the thickness of the eighth conductive layer ML8 may be 9,000 Å (or approximately 9,000 Å). Each of the thicknesses of the seventh via electrode VA7 and the eighth via electrode VA8 may be 6,000 Å (or approximately 6,000 Å).

A ninth insulating layer INS9 may be located on the eighth insulating layer INS8 and the eighth conductive layer ML8. The ninth insulating layer INS9 may include a silicon oxide (SiOₓ)-based inorganic film, but the embodiments of the present disclosure are not limited thereto.

Each ninth via electrode VA9 may be connected to the eighth conductive layer ML8 exposed by penetrating through the ninth insulating layer INS9. The ninth via electrodes VA9 may include any one of copper (Cu), aluminum (Al), tungsten (W), molybdenum (Mo), chromium (Cr), gold (Au), titanium (Ti), nickel (Ni), and neodymium (Nd), or an alloy including any one thereof. A thickness of the ninth via electrode VA9 may be 16,500 Å (or approximately 16,500 Å).

The display element layer EML may be located on the light emitting element backplane EBP. The display element layer EML may include a plurality of barrier electrodes BRE, a plurality of reflective electrodes RL, a middle layer 123, a plurality of first electrodes AND, a light emitting stack layer IL, a second electrode CAT, and a bank layer BKL. Here, the middle layer 123 may include a plurality of capping layers CPL and a plurality of planarization layers PNS. In this case, the middle layer 123 may further include a plurality of protective layers PTL in addition to the plurality of capping layers CPL and the plurality of planarization layers PNS. In addition, the bank layer BKL may include a first bank BK1 and a second bank BK2 on the first bank BK1.

In addition, the display element layer EML may include a first light emitting area EA1, a second light emitting area EA2, and a third light emitting area EA3. Each of the first light emitting area EA1, the second light emitting area EA2, and the third light emitting area EA3 may be an area in which the first electrode AND, the light emitting stack layer IL, and the second electrode CAT are sequentially stacked. Each of the first light emitting area EA1, the second light emitting area EA2, and the third light emitting area EA3 may be an area in which the light emitting element LE including the first electrode AND, the light emitting stack layer IL, and the second electrode CAT is located. Each of the first light emitting area EA1, the second light emitting area EA2, and the third light emitting area EA3 may be partitioned by the capping layer CPL.

The plurality of barrier electrodes BRE may be located on the ninth insulating layer INS9. For example, the plurality of barrier electrodes BRE may be located on the ninth insulating layer INS9 so as to be respectively connected to the plurality of ninth via electrodes VA9. The barrier electrode BRE may prevent or reduce diffusion of a material (e.g., aluminum) included in the reflective electrode RL. The plurality of barrier electrodes BRE may include titanium nitride (TiN) or transparent conductive oxide. For example, the transparent conductive oxide may be Indium Tin Oxide (ITO) or Indium Zinc Oxide (IZO), but the embodiments of the present disclosure are not limited thereto.

The plurality of reflective electrodes RL may be respectively located on the plurality of barrier electrodes BRE. Each reflective electrode RL may include any one of copper (Cu), aluminum (Al), tungsten (W), molybdenum (Mo), chromium (Cr), gold (Au), titanium (Ti), nickel (Ni), and neodymium (Nd), or an alloy including any one thereof. For example, each reflective electrode RL may include aluminum (Al) having high reflectivity.

A step layer STPL may be located on the reflective electrode RL in each of the second sub-pixel areas SP2 and the third sub-pixel areas SP3. The step layer STPL may not be located in each of the first sub-pixel areas SP1. For example, the step layer STPL may be located between the reflective electrode RL and a resonance control layer RCL in the second sub-pixel area SP2 and the third sub-pixel area SP3 among the plurality of sub-pixel areas SP1, SP2, and SP3. The step layer STPL may be a layer (e.g., a step level-inducing layer) that induces a step level (height difference) between the sub-pixel areas (e.g., SP1 and SP2) that emit light of different colors (or different wavelength bands). The step layer STPL may include a silicon carbon nitride (SiCN) or silicon oxide (SiOₓ)-based inorganic film, but the embodiments of the present specification are not limited thereto.

Resonance control layers RCL may be respectively located on the reflective electrodes RL and the step layers STPL. The resonance control layer RCL may include a silicon oxide (SiOₓ)-based inorganic film, but the embodiments of the present disclosure are not limited thereto.

In each of the first sub-pixel areas SP1, the resonance control layer RCL may be located on the reflective electrode RL. For example, in each of the first sub-pixel areas SP1, the resonance control layer RCL may cover an upper surface of the reflective electrode RL.

In each of the second sub-pixel areas SP2, the resonance control layer RCL may be located on the reflective electrode RL and the step layer STPL. For example, in each of the second sub-pixel areas SP2, the resonance control layer RCL may cover an edge of an upper surface of the reflective electrode RL, an upper surface of the step layer STPL, and a side surface of the step layer STPL.

In each of the third sub-pixel areas SP3, the resonance control layer RCL may be located on the reflective electrode RL and the step layer STPL. For example, in each of the third sub-pixel areas SP3, the resonance control layer RCL may cover an edge of an upper surface of the reflective electrode RL, an upper surface of the step layer STPL, and a side surface of the step layer STPL.

Due to the step layer STPL, a height HT1 of the resonance control layer RCL in the first light emitting area EA1 of the first sub-pixel area SP1, a height HT2 of the resonance control layer RCL in the second light emitting area EA2 of the second sub-pixel area SP2, and a height HT3 of the resonance control layer RCL in the third light emitting area EA3 of the third sub-pixel area SP3 may be different. For example, the height HT1 of the resonance control layer RCL in the first light emitting area EA1 may be the smallest. The height HT2 of the resonance control layer RCL in the second light emitting area EA2 may be greater than the height HT1 of the resonance control layer RCL in the first light emitting area EA1. The height HT3 of the resonance control layer RCL in the third light emitting area EA3 may be the same as the height HT2 of the resonance control layer RCL in the second light emitting area EA2. In this way, the height of the resonance control layer RCL in the first light emitting area EA1, the second light emitting area EA2, and the third light emitting area EA3 may vary depending on the thickness and number of step layers. The height of the resonance control layer RCL may be set in consideration of a main peak wavelength of the first light, a main peak wavelength of the second light, a main peak wavelength of the third light, a distance from the first stack layer of the light emitting stack layer to the reflective electrode RL in the first light emitting area EA1, a distance from the second stack layer of the light emitting stack layer to the reflective electrode RL in the second light emitting area EA2, and a distance from the third stack layer of the light emitting stack layer to the reflective electrode RL in the third light emitting area EA3, and accordingly, a resonance distance of the first light, a resonance distance of the second light, and a resonance distance of the third light may be set. Here, the height of the resonance control layer RCL in each of the light emitting areas EA1, EA2, and EA3 may be defined as a distance from the upper surface of the reflective electrode RL to the upper surface of the resonance control layer RCL in the corresponding light emitting area.

For example, the height HT1 of the resonance control layer RCL in the first light emitting area EA1 described above may be defined as a distance (e.g., a distance in the third direction DR3) between the upper surface of the reflective electrode RL (e.g., an interface between the reflective electrode RL and the resonance control layer RCL) and the upper surface of the resonance control layer RCL (e.g., an interface between the resonance control layer RCL and the first electrode AND) in the first light emitting area EA1, the height HT2 of the resonance control layer RCL in the second light emitting area EA2 described above may be defined as a distance (e.g., a distance in the third direction DR3) between the upper surface of the reflective electrode RL (e.g., an interface between the reflective electrode RL and the step layer STPL) and the upper surface of the resonance control layer RCL (e.g., an interface between the resonance control layer RCL and the first electrode AND) in the second light emitting area EA2, and the height HT3 of the resonance control layer RCL in the third light emitting area EA3 described above may be defined as a distance (e.g., a distance in the third direction DR3) between the upper surface of the reflective electrode RL (e.g., an interface between the reflective electrode RL and the step layer STPL) and the upper surface of the resonance control layer RCL (e.g., an interface between the resonance control layer RCL and the first electrode AND) in the third light emitting area EA3. Because no step layer is located in the first light emitting area, the height HT1 of the resonance control layer RCL in the first light emitting area EA1 described above may be the same (or substantially the same) as the thickness of the resonance control layer RCL in the first light emitting area EA1.

The resonance control layer RCL may be located between the reflective electrode RL and a first electrode AND (e.g., an upper electrode portion 1001).

Each of the light emitting elements LE may include a first electrode AND, a light emitting stack layer IL, and a second electrode CAT.

The first electrode AND of each of the light emitting elements LE may be located on a side surface of the barrier electrode BRE, a side surface of the reflective electrode RL, an upper surface of the resonance control layer RCL, and a side surface of the resonance control layer RCL. The first electrode AND of each of the light emitting elements LE may be electrically connected by being in contact with the side surface of the reflective electrode RL and the side surface of the barrier electrode BRE.

The first electrode AND may include an upper electrode portion 1001 located on the upper surface of the resonance control layer RCL so as to overlap the upper surface of the reflective electrode RL, and a side electrode portion 1002 extending from the upper electrode portion 1001 to the semiconductor substrate SSUB.

The side electrode portion 1002 of the first electrode AND may be located on the side surface of the resonance control layer RCL, the side surface of the reflective electrode RL, and the side surface of the barrier electrode BRE. The side surface of the resonance control layer RCL may be a surface connecting the upper surface and the lower surface of the resonance control layer RCL facing each other in the third direction DR3. The upper surface among the upper and lower surfaces of the resonance control layer RCL may be located further away from the semiconductor substrate SSUB, and the lower surface among the upper and lower surfaces of the resonance control layer RCL may be located closer to the semiconductor substrate SSUB. In addition, the side surface of the reflective electrode RL may be a surface connecting the upper surface and the lower surface of the reflective electrode RL facing each other in the third direction DR3. The upper surface among the upper and lower surfaces of the reflective electrode RL may be located further away from the semiconductor substrate SSUB, and the lower surface among the upper and lower surfaces of the reflective electrode RL may be located closer to the semiconductor substrate SSUB. In addition, the side surface of the barrier electrode BRE may be a surface connecting the upper surface and the lower surface of the barrier electrode BRE facing each other in the third direction DR3. The upper surface among the upper and lower surfaces of the barrier electrode BRE may be located further away from the semiconductor substrate SSUB, and the lower surface among the upper and lower surfaces of the barrier electrode BRE may be located closer to the semiconductor substrate SSUB.

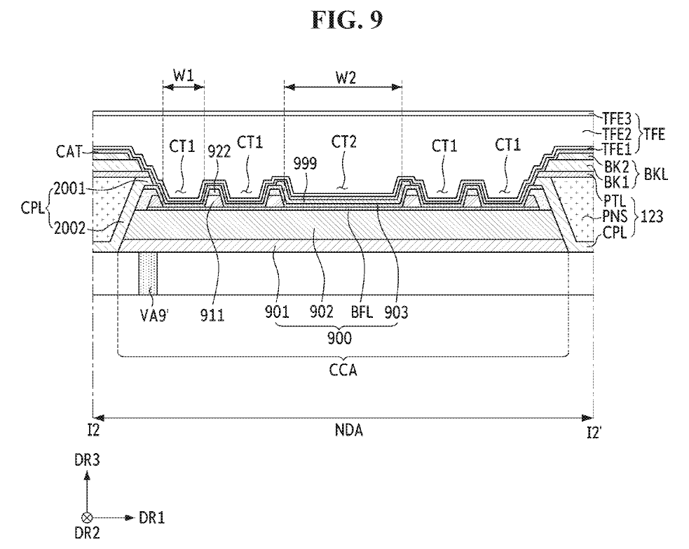

A thickness TK1 of the first electrode AND on the side surface of the resonance control layer RCL, the side surface of the reflective electrode RL, and the side surface of the barrier electrode BRE may be different from a thickness TK2 of the first electrode AND on the upper surface of the resonance control layer RCL. For example, the thickness TK1 of the first electrode AND on the side surface of the resonance control layer RCL, the side surface of the reflective electrode RL, and the side surface of the barrier electrode BRE may be smaller than the thickness TK2 of the first electrode AND on the upper surface of the resonance control layer RCL. As a specific example, as illustrated in FIG. 9, the thickness TK1 of the side electrode portion 1002 of the first electrode AND may be smaller than the thickness TK2 of the upper electrode portion 1001 of the first electrode AND. According to some embodiments, the thickness TK1 of the side electrode portion 1002 may be 65Å (or approximately 65Å), and the thickness TK2 of the upper electrode portion 1001 may be 110Å (or approximately 110Å).

The first electrode AND of each of the light emitting elements LE may be connected to the drain area DA or the source area SA of the pixel transistor PTR through the barrier electrode BRE, the first to ninth via electrodes VA1 to VA9, the first to eighth conductive layers ML1 to ML8, and the contact terminal CTE.

The first electrodes AND of the sub-pixel areas SP1, SP2, and SP3 may be disconnected so as not to be connected to each other. For example, the side electrode portion 1002 of the first electrode AND located in the first sub-pixel area SP1 may be disconnected from the side electrode portion 1002 of the first electrode AND located in the second sub-pixel area SP2, and the side electrode portion 1002 of the first electrode AND located in the second sub-pixel area SP2 may be disconnected from the side electrode portion 1002 of the first electrode AND located in the third sub-pixel area SP3. In other words, when a structure including a plurality of first electrodes AND located in the plurality of sub-pixel areas SP1, SP2, and SP3 is defined as one first electrode structure, the first electrode structure may be disconnected between the sub-pixel areas SP1, SP2, and SP3 adjacent to each other. The first electrode AND of each of the light emitting elements LE may include a transparent conductive material. For example, the first electrode may be made of a material including indium-tin-oxide (ITO). Unlike this, the first electrode AND may include any one of copper (Cu), aluminum (Al), tungsten (W), molybdenum (Mo), chromium (Cr), gold (Au), titanium (Ti), nickel (Ni), and neodymium (Nd), or an alloy including any one thereof. For example, the first electrode AND of each of the light emitting elements LE may include titanium nitride (TiN).

The middle layer 123 may be located on the first electrodes AND. For example, the middle layer 123 may be located on an edge of each first electrode AND. In other words, the middle layer 123 may be located on each first electrode AND so as not to overlap each of the light emitting areas EA1, EA2, and EA3. For example, the middle layer 123 may define each of the light emitting areas EA1, EA2, and EA3. In other words, the middle layer 123 may have an opening defining each of the light emitting areas EA1, EA2, and EA3. As described above, the middle layer 123 may include a capping layer CPL, a planarization layer PNS, and a protective layer PTL.

The capping layer CPL may partition the first light emitting areas EA1, the second light emitting areas EA2, and the third light emitting areas EA3. The capping layer CPL may be located on a partial area of the first electrode AND of each of the light emitting elements LE. The capping layer CPL may cover an edge of the first electrode AND of each of the light emitting elements LE. The capping layer CPL may be made of a material including silicon nitride (SiNx). In some embodiments, as the capping layer CPL includes a different material from the planarization layer PNS described later, the capping layer CPL may function as an etch stop film that defines a thickness (or height) of the planarization layer PNS, when the planarization layer PNS is removed by chemical mechanical polishing (CMP).

The capping layer CPL may define each of the light emitting areas EA1, EA2, and EA3. The capping layer CPL may be located on the first electrode AND. For example, the capping layer CPL may be located on the upper surface of the first electrode AND and on the side surface of the first electrode AND. In this case, the capping layer CPL may be located on an edge of the upper surface of the first electrode AND. The capping layer CPL may include an upper capping portion 2001 located on the upper electrode portion 1001 of the first electrode AND and a side capping portion 2002 located on the side electrode portion 1002 of the first electrode AND. The capping layer CPL may be in contact with (or in direct contact with) the first electrode AND.

The first light emitting area EA1 may be defined as an area in which the first electrode AND, the light emitting stack layer IL, and the second electrode CAT are sequentially stacked in the first sub-pixel area SP1 to emit light. The second light emitting area EA2 may be defined as an area in which the first electrode AND, the light emitting stack layer IL, and the second electrode CAT are sequentially stacked in the second sub-pixel area SP2 to emit light. The third light emitting area EA3 may be defined as an area in which the first electrode AND, the light emitting stack layer IL, and the second electrode CAT are sequentially stacked in the third sub-pixel area SP3 to emit light.

The planarization layer PNS may be a planarization layer capable of planarizing the step difference between sub-pixel areas SP1, SP2, and SP3 caused by the step layer STPL. The planarization layer PNS may be located on the capping layer CPL. For example, the planarization layer PNS may be located on upper and side surfaces of the capping layer CPL. In this case, The planarization layer PNS may be in contact (or in direct contact) with the capping layer CPL and also in contact (or in direct contact) with the first electrode AND. The planarization layer PNS may be made of a material including silicon oxide (SiOx).

The protective layer PTL may be located on the planarization layer PNS and the capping layer CPL. The protective layer PTL may include the same material as the planarization layer PNS. For example, the protective layer PTL may be made of a material including silicon oxide (SiOx). In such a case, the protective layer PTL and the planarization layer PNS may be integrally formed without an interface.

The bank layer BKL may be located on the middle layer 123. For example, the bank layer BKL may be located on the protective layer PTL. The bank layer BKL may include a first bank BK1 and a second bank BK2, as described above. In a plan view, as illustrated in FIG. 4, the bank layer BKL may have a mesh shape surrounding each of the light emitting areas EA1, EA2, and EA3. The bank layer BKL may be located on the protective layer PTL to surround each of the light emitting areas EA1, EA2, and EA3. However, the present disclosure is not limited thereto, and a configuration in which a plurality of bank layers each surround the plurality of light emitting areas EA1, EA2, and EA3 is also possible. In such a case, each bank layer BKL may have a shape of a closed curve. The bank layer BKL may be a structure for cutting the light emitting stack layer IL. To this end, according to some embodiments, the bank layer BKL may include a first bank BK1 and a second bank BK2 having different areas.

The first bank BK1 may be located on the protective layer PTL. The first bank BK1 may be located on the protective layer PTL to overlap the capping layer CPL. In this case, the area of the first bank BK1 may be smaller than the area of the protective layer PTL. For example, in a plan view, the area of the first bank BK1 may be smaller than the area of the protective layer PTL so that the first bank BK1 may be surrounded by the edge of the protective layer PTL. The first bank may be made of a material including at least one of titanium (Ti), tantalum (Ta), or molybdenum (Mo).

The second bank BK2 may be located on the first bank BK1. The second bank BK2 may be located on the first bank BK1 to overlap the first bank BK1. In this case, in the display area DAA, the area of the second bank BK2 may be greater than the area of the first bank BK1. For example, in a plan view, the area of the second bank BK2 in the display area DAA may be greater than the area of the first bank BK1 so that the second bank BK2 of the display area DAA may surround the edge of the first bank BK1 of the display area DAA. In other words, because the second bank BK2 may include a tip TP at the edge, the tip TP of the second bank BK2 may not overlap the first bank BK1. Accordingly, the bank layer BKL in the display area DAA (e.g., sub-pixel area) may have an undercut structure. An etching rate of the first bank BK1 may be different from an etching rate of the second bank BK2. For example, the etching rate of the first bank BK1 may be greater than the etching rate of the second bank BK2. The second bank BK2 may be made of a material including silicon oxide (SiOx).

The light emitting stack layer IL may be located on the first electrodes AND, the capping layer CPL, and the bank layer BKL. In this case, the light emitting stack layer IL may be cut on the bank layer BKL. For example, the light emitting stack layer IL may be cut between the protective layer PTL and the second bank BK2. In cross-section view, the light emitting stack layer IL may be cut along the bank layer BKL. Therefore, the light emitting stack layer IL may be divided into a portion in contact with the first electrode AND in the light emitting area and a portion located on an area excluding the light emitting area (e.g., the second bank BK2 of the bank layer BKL). In other words, the light emitting stack layer IL may be cut along the bank layer BKL to be separated for each sub-pixel area. Accordingly, lateral leakage current between the sub-pixel areas SP1, SP2, and SP3 adjacent to each other may be minimized. As the lateral leakage current is minimized, color mixing between the sub-pixel areas SP1, SP2, and SP3 adjacent to each other may be prevented or reduced, thereby relatively improving an image quality of the display device 10.

The light emitting stack layer IL may include a plurality of stack layers sequentially stacked along the third direction DR3. For example, the light emitting stack layer IL may have a three-tandem structure including a first stack layer, a second stack layer on the first stack layer, and a third stack layer on the second stack layer.

Here, the second stack layer may be located between the first stack layer and the third stack layer. The embodiments of the present disclosure are not limited thereto. For example, the light emitting stack layer IL may also have a two-tandem structure including two stack layers.

In the three-tandem structure, the first stack layer, the second stack layer, and the third stack layer of the light emitting stack layer IL may provide light of different colors (or wavelengths). For example, one of the first stack layer, the second stack layer, and the third stack layer may provide light of a first color (e.g., green), another of the first stack layer, the second stack layer, and the third stack layer may provide light of a second color (e.g., red), and the other of the first stack layer, the second stack layer, and the third stack layer may provide light of a third color (e.g., blue).

The first stack layer of the light emitting stack layer IL may have a structure in which a first hole transporting layer, a first organic light emitting layer, and a first electron transporting layer are sequentially stacked. The second stack layer of the light emitting stack layer IL may have a structure in which a second hole transporting layer, a second organic light emitting layer, and a second electron transporting layer are sequentially stacked. The third stack layer of the light emitting stack layer IL may have a structure in which a third hole transporting layer, a third organic light emitting layer, and a third electron transporting layer are sequentially stacked. Here, the first organic light emitting layer, the second organic light emitting layer, and the third organic light emitting layer may provide light of different colors (or wavelengths). For example, one of the first organic light emitting layer, the second organic light emitting layer, and the third organic light emitting layer may provide light of a first color (e.g., green), another of the first organic light emitting layer, the second organic light emitting layer, and the third organic light emitting layer may provide light of a second color (e.g., red), and the other of the first organic light emitting layer, the second organic light emitting layer, and the third organic light emitting layer may provide light of a third color (e.g., blue).

A first charge generating layer for supplying charges to the second stack layer and supplying electrons to the first stack layer may be located between the first stack layer and the second stack layer. The first charge generating layer may include an n-type charge generating layer that supplies electrons to the first stack layer and a p-type charge generating layer that supplies holes to the second stack layer. The n-type charge generating layer may include a dopant of a metallic material.

A second charge generating layer for supplying charges to the third stack layer and supplying electrons to the second stack layer may be located between the second stack layer and the third stack layer. The second charge generating layer may include an n-type charge generating layer that supplies electrons to the second stack layer and a p-type charge generating layer that supplies holes to the third stack layer.

The first stack layer may be located on the first electrodes AND and the capping layer CPL. By means of the bank layer BKL described above, the first stack layer of the light emitting stack layer IL may be disconnected between the sub-pixel areas SP1, SP2, and SP3 adjacent to each other. The second stack layer of the light emitting stack layer IL may be located on the first stack layer. By means of the bank layer BKL described above, the second stack layer of the light emitting stack layer IL may be disconnected between the sub-pixel areas SP1, SP2, and SP3 adjacent to each other. The third stack layer of the light emitting stack layer IL may be located on the second stack layer. The third stack layer of the light emitting stack layer IL may not be disconnected by the bank layer BKL and may be arranged to cover the second stack layer.

In the three-tandem structure, the bank layer BKL may be a structure for disconnecting the first charge generating layer and the second charge generating layer of the display element layer EML between the sub-pixel areas SP1, SP2, and SP3 adjacent to each other. In addition, in the two-tandem structure, the bank layer BKL may be a structure for disconnecting a charge generating layer located between a lower stack layer and an upper stack layer.

The second electrode CAT may be located on the light emitting stack layer IL. For example, the second electrode CAT may be located on the third stack layer of the light emitting stack layer IL. The second electrode CAT may not be disconnected by the bank layer BKL and may be located on the third stack layer of the light emitting stack layer IL. The second electrode CAT may include a semi-transmissive conductive material such as magnesium (Mg), silver (Ag), or an alloy of magnesium (Mg) and silver (Ag). In this case, light emission efficiency may be increased in each of the first to third sub-pixel areas SP1, SP2, and SP3 by micro cavities.

The encapsulation layer TFE may be located on the display element layer EML. The encapsulation layer TFE may include at least one inorganic layer to prevent or reduce contaminants such as oxygen or moisture permeating into the display element layer EML. For example, the encapsulation layer TFE may include a first encapsulation layer TFE1, a second encapsulation layer TFE2, and a third encapsulation layer TFE3.

The first encapsulation layer TFE1 may be located on the second electrode CAT. The first encapsulation layer TFE1 may be formed as a multi-film in which one or more inorganic films of silicon nitride (SiNₓ), silicon oxide nitride (SiON), and silicon oxide (SiOₓ) are alternately stacked. The first encapsulation layer TFE1 may be formed by a chemical evaporation deposition (CVD) process.

The second encapsulation layer TFE2 may be a monomer. Alternatively, the second encapsulation layer TFE2 may be an organic film made of an acrylic resin, an epoxy resin, a phenolic resin, a polyamide resin, or a polyimide resin.

The third encapsulation layer TFE3 may be located on the second encapsulation layer TFE2. The third encapsulation layer TFE3 may be formed as a multi-film in which one or more inorganic films of silicon nitride (SiNₓ), silicon oxide nitride (SiON), and silicon oxide (SiOₓ) are alternately stacked. The third encapsulation layer TFE3 may be formed by a chemical evaporation deposition (CVD) process.

The organic layer APL may be a layer for increasing an interfacial adhesion between the encapsulation layer TFE and the optical layer OPL. The organic layer APL may be an organic film made of an acryl resin, an epoxy resin, a phenolic resin, a polyamide resin, a polyimide resin, or the like.

The optical layer OPL includes a plurality of color filters CF1, CF2, and CF3, a plurality of lenses LNS, and a filling layer FIL. The plurality of color filters CF1, CF2, and CF3 may include first to third color filters CF1, CF2, and CF3. The first to third color filters CF1, CF2, and CF3 may be located on the adhesive layer ADL.

The first color filter CF1 may overlap the first light emitting area EA1 of the first sub-pixel area SP1. The first color filter CF1 may transmit first light (e.g., light in a green wavelength band). Therefore, the first color filter CF1 may transmit the first light among light emitted from the light emitting stack layer IL of the first light emitting area EA1.

The second color filter CF2 may overlap the second light emitting area EA2 of the second sub-pixel area SP2. The second color filter CF2 may transmit second light (e.g., light in a red wavelength band). Therefore, the second color filter CF2 may transmit the second light among light emitted from the light emitting stack layer IL of the second light emitting area EA2.

The third color filter CF3 may overlap the third light emitting area EA3 of the third sub-pixel area SP3. The third color filter CF3 may transmit third light (e.g., light in a blue wavelength band). Therefore, the third color filter CF3 may transmit the third light among light emitted from the light emitting stack layer IL of the third light emitting area EA3.

Each of the plurality of lenses LNS may be located on each of the first color filter CF1, the second color filter CF2, and the third color filter CF3. Each of the plurality of lenses LNS may be a structure for increasing a ratio of light directed to the front of the display device 10. It is illustrated that each of the plurality of lenses LNS has a cross-sectional shape that is convex in an upward direction, but the embodiments of the present disclosure are not limited thereto.

The filling layer FIL may be located on the plurality of lenses LNS. The filling layer FIL may have a refractive index so that light travels in the third direction DR3 at an interface between the plurality of lenses LNS and the filling layer FIL. In addition, the filling layer FIL may be a planarization layer. The filling layer FIL may be an organic film made of an acryl resin, an epoxy resin, a phenolic resin, a polyamide resin, a polyimide resin, or the like.

The cover layer CVL may be located on the filling layer FIL. The cover layer CVL may be a glass substrate or a polymer resin such as resin. When the cover layer CVL is a glass substrate, the cover layer CVL may be attached onto the filling layer FIL. In this case, the filling layer FIL may serve to attach the cover layer CVL. When the cover layer CVL is a glass substrate, the cover layer CVL may serve as an encapsulation substrate. When the cover layer CVL is a polymer resin such as resin, the cover layer CVL may be directly applied onto the filling layer FIL.

The polarizing plate POL may be located on one surface of the cover layer CVL. The polarizing plate POL may be a structure for preventing or reducing deterioration in visibility due to reflection of external light. The polarizing plate POL may include a linear polarizing plate and a phase retardation film. For example, the phase retardation film may be a λ/4 (quarter-wave) plate, but the embodiments of the present disclosure are not limited thereto. However, when the deterioration in visibility due to the reflection of external light is sufficiently reduced by the first to third color filters CF1, CF2, and CF3, the polarizing plate POL may also be omitted.

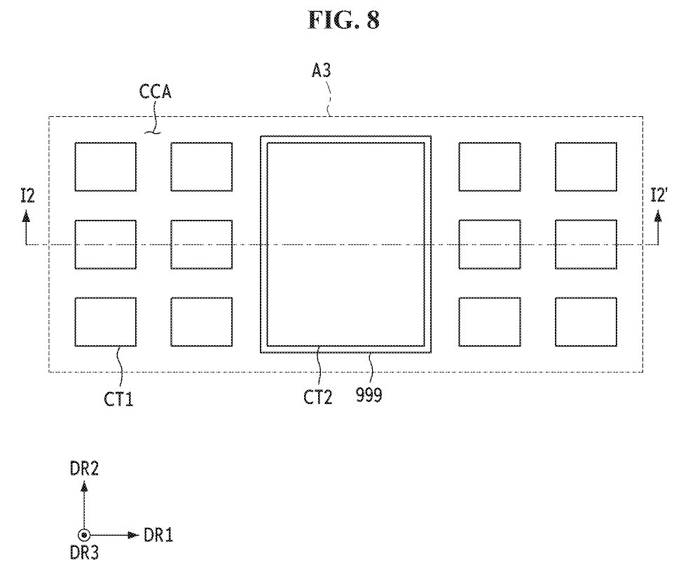

FIG. 8 is an enlarged view of area A3 of FIGS. 3 and 9 is a cross-sectional view illustrating an example of the display panel 100 taken along the line I2-I2’ of FIG. 8.

Referring to FIG. 8, a power connection area CCA may be located on the non-display area NDA of the semiconductor substrate SSUB.

A power connection electrode 900, a buffer layer BFL, a first auxiliary layer 911, a second auxiliary layer 922, and a capping layer CPL may be located in the power connection area CCA. Here, the power connection electrode 900 may include a first power connection electrode 901, a second power connection electrode 902, a buffer layer BFL, and a third power connection electrode 903.

The first power connection electrode 901 may be located on the ninth insulating layer INS9. The first power connection electrode 901 may be connected to a power line on the semiconductor substrate SSUB through a ninth via electrode VA9’. The power line may be connected to, for example, the power supply unit 500 to receive power (e.g., the first driving voltage VSS). The first power connection electrode 901 may be located at the same layer as the barrier electrode BRE described above. The first power connection electrode 901 may include the same material as the barrier electrode BRE described above.

The second power connection electrode 902 may be located on the first power connection electrode 901. The second power connection electrode 902 may be located at the same layer as the reflective electrode RL described above. The second power connection electrode 902 may include the same material as the reflective electrode RL described above.

The buffer layer BFL may be located on the second power connection electrode 902. The buffer layer BFL may be located on an upper surface of the second power connection electrode 902. The buffer layer BFL may be in contact (or in direct contact) with the second power connection electrode 902. The buffer layer BFL may prevent or reduce instances of an oxide layer forming on the second power connection electrode 902. The second power connection electrode 902 and the third power connection electrode 903 are connected to each other through the buffer layer BFL, and thus contact resistance between the second power connection electrode 902 and the third power connection electrode 903 may be reduced. The buffer layer BFL may include titanium nitride (TiN). The buffer layer BFL may have a thickness of smaller than or equal to 10 Å (or approximately 10 Å).

The first auxiliary layer 911 may be located on the buffer layer BFL. The first auxiliary layer 911 may include the same material as the step layer STPL described above.

The second auxiliary layer 922 may be located on the first auxiliary layer 911 and the second power connection electrode 902. The second auxiliary layer 922 may include the same material as the resonance control layer RCL described above.

The third power connection electrode 903 may be located on the second auxiliary layer 922. The third power connection electrode 903 may have a rough shape. The third power connection electrode 903 may be connected to the buffer layer BFL through a first contact hole CT1 and a second contact hole CT2 penetrating through the second auxiliary layer 922 and the first auxiliary layer 911. The third power connection electrode 903 may be located at the same layer as the first electrode AND described above. The third power connection electrode 903 may include the same material as the first electrode AND described above.

A test element group (TEG) layer 999 may be located on the third power connection electrode. For example, the TEG layer 999 may be located on the third power connection electrode 903 to overlap the second contact hole CT2 penetrating through the second auxiliary layer 922 and the first auxiliary layer 911. The TEG layer 999 may be connected to the third power connection electrode 903 through the second contact hole CT2. The TEG layer 999 and the third power connection electrode 903 may be in contact (or in direct contact) with each other. The TEG layer 999 may include the same material as the light emitting stack layer (IL) described above. The TEG layer 999 may be, for example, a dummy pattern for measuring a thickness of the light emitting stack layer IL located in the display area DAA (e.g., the sub-pixel area or the light emitting area). The thickness of the light emitting stack layer IL in the display area DAA (e.g., the sub-pixel area or the light emitting area) may be indirectly measured by measuring the thickness of the TEG layer 999. Therefore, when the measured thickness of the TEG layer 999 satisfies a preset reference value, the thickness of the light emitting stack layer IL may also be determined to satisfy the reference value described above. The thickness of the TEG layer 999 may be calculated, for example, based on a round trip time of a laser light irradiated onto the TEG layer 999.

The first contact hole CT1 and the second contact hole CT2 may be located in the power connection area CCA. The first contact hole CT1 and the second contact hole CT2 may have different areas. For example, in a plan view as illustrated in FIG. 8, the area of the second contact hole CT2 may be greater than the area of the first contact hole CT1. As illustrated in FIG. 9, a width W2 of the second contact hole CT2 may be greater than a width W1 of the first contact hole CT1. In addition, a length of the second contact hole CT2 may be greater than a length of the first contact hole CT1. Here, the width of each of the contact holes CT1 and CT2 may be a size of the corresponding contact hole in the first direction DR1, and the length of each of the contact holes CT1 and CT2 may be a size of the corresponding contact hole in the second direction DR2.

The capping layer CPL described above may be located on the third power connection electrode 903 in the power connection area CCA. For example, the upper capping portion 2001 of the capping layer CPL may be located on the third power connection electrode 903 in the power connection area CCA.

The second electrode CAT described above may be connected to the third power connection electrode 903 through the first contact holes CT1 of the power connection area CCA.

In addition, the second electrode CAT may be connected to the TEG layer 999 through the second contact holes of the power connection area CCA.

The bank layer BKL adjacent to the power connection area CCA may have a different structure from the bank layer BKL of the display area DAA. For example, the bank layer BKL may have cross-sections of different shapes in the display area DAA and the non-display area NDA. For example, the second bank BK2 of the bank layer BKL in the area adjacent to the power connection area CCA does not have a tip TP. In other words, an edge of the second bank BK2 of the bank layer BKL in the non-display area NDA may overlap the first bank BK1. In a plan view, an edge of the first bank BK1 of the non-display area NDA may surround the second bank BK2 of the non-display area NDA. Accordingly, the bank layer BKL in the non-display area NDA (e.g., the power connection area CCA) may have a non-undercut structure.

The encapsulation layer TFE may be located on the power connection area CCA. For example, the first encapsulation layer TFE1, the second encapsulation layer TFE2, and the third encapsulation layer TFE3 may be located on the power connection area CCA. Here, the first encapsulation layer TFE1 may be located on the second electrode CAT to overlap the TEG layer 999 in the power connection area CCA.

According to some embodiments, because the width of the second bank BK2 of the non-display area NDA is smaller than the width of the first bank BK1, the second electrode CAT located on the first bank BK1 and the second bank BK2 of the non-display area NDA may not be disconnected. Accordingly, even though the bank layer BKL is located in the non-display area NDA, disconnection of the second electrode CAT in the non-display area NDA may be prevented or reduced. Accordingly, the second electrode CAT and the third power connection electrode 903 may be normally connected in the power connection area CCA of the non-display area NDA. Because the second electrode CAT in the display area DAA is supported by the light emitting stack layer IL, the second electrode CAT located on the second bank BK2 of the display area DAA may not be disconnected.

According to some embodiments, because the TEG layer is formed in a guaranteed area (e.g., the power connection area), a quality of the TEG layer 999 (e.g., a thickness of the TEG layer 999) may be guaranteed. For example, because the TEG layer 999 is formed within the area of the display panel 100 that is actually used as a product, rather than a non-guaranteed area such as an edge of a wafer, the quality of the TEG layer 999 may be the same (or substantially the same) as the quality of the light emitting stack layer IL. Therefore, the thickness of the TEG layer 999 in the power connection area may be the same (or substantially the same) as the thickness of the light emitting stack layer in the light emitting area, and thus the thickness of the TEG layer 999 may relatively accurately reflect the thickness of the light emitting stack layer. Therefore, according to some embodiments, whether the thickness of the light emitting stack layer is defective may be relatively accurately determined.

When the TEG layer 999 is formed in the non-guaranteed area such as the edge of the wafer, the thickness of the TEG layer 999 on the buffer layer BFL may also be unevenly formed, because the thickness of the buffer layer BFL at the edge of the wafer is uneven. Therefore, when the TEG layer 999 is formed in the non-guaranteed area of the wafer, the thickness of the TEG layer 999 may not accurately reflect the thickness of the light emitting stack layer IL in the guaranteed area (e.g., the sub-pixel area or the display area DAA). Therefore, when the TEG layer 999 is formed at the edge of the wafer, it is difficult to determine whether the thickness of the light emitting stack layer IL is defective.

The display device 10 according to some embodiments may be applied to various electronic devices. An electronic device according to some embodiments may include the display device 10 described above, and may further include a module or device having additional functions in addition to the display device 10.

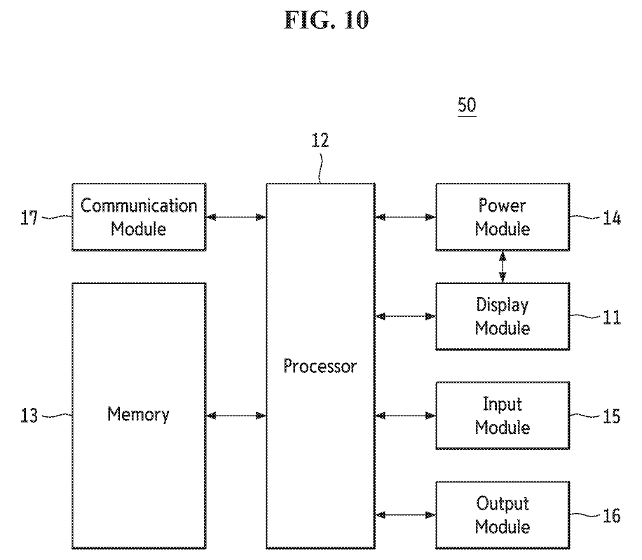

FIG. 10 is a block diagram of an electronic device according to some embodiments. Referring to FIG. 10, an electronic device 50 according to some embodiments may include a display module 11, a processor 12, a memory 13, and a power module 14. The electronic device 50 may further include an input module 15, a non-image output module 16, and/or a communication module 17.

The electronic device 50 may output various information in the form of an image through the display module 11. When the processor 12 executes an application stored in the memory 13, image information provided by the application may be provided to the user through the display module 11. The power module 14 may include a power supply module, such as a power adapter or a battery device, and a power conversion module that converts power supplied by the power supply module to generate power required for an operation of the electronic device 50. The input module 15 may provide input information to the processor 12 and/or the display module 11. The non-image output module 16 may serve to receive information other than the image received from the processor 12, such as sound, haptics, and light emission, and provide the information to the user. The communication module 17 is a module responsible for transmitting and receiving information between the electronic device 50 and an external device, and may include a receiving unit and a transmitting unit.

At least one of the components of the electronic device 50 described above may be included in the display device according to the above-described embodiments. In addition, some of the individual modules functionally included within one module may be included within the display device, while others may be provided separately from the display device. For example, the display device includes the display module 11, and the processor 12, the memory 13, and the power module 14 may be provided in the form of other devices within the electronic device 50 other than the display device.

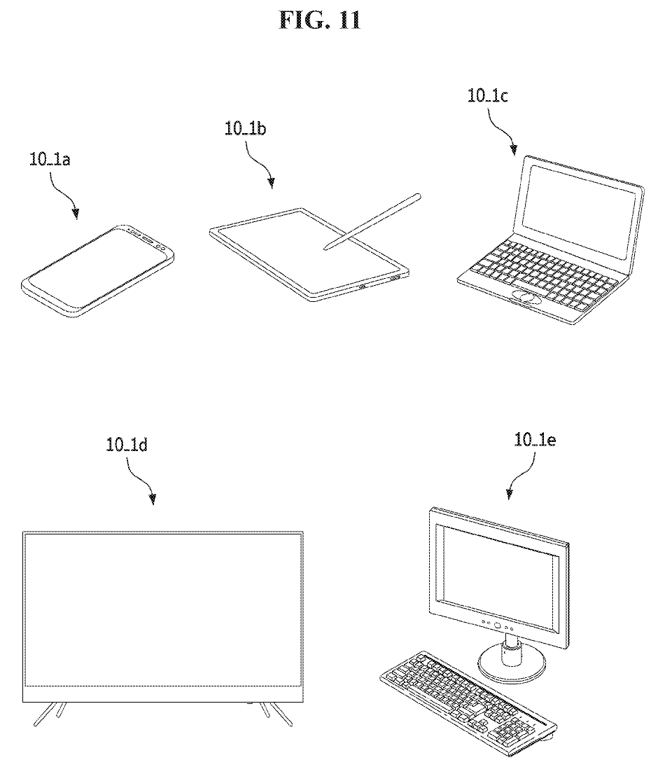

FIGS. 11, 12 and 13 are schematic diagrams of electronic devices according to various embodiments. FIGS. 11-13 illustrate examples of various electronic devices to which the display device 10 according to the embodiments is applied.

FIG. 11 illustrates examples of the electronic devices, including a smartphone 10_1a, a tablet PC 10_1b, a laptop 10_1c, a TV 10_1d, and a desk monitor 10_1e.

The smartphone 10_1a may include an input module such as a touch sensor and a communication module in addition to the display module 11. The smartphone 10_1a may process information received through the communication module or other input modules and display the information through the display module of the display device.

The tablet PC 10_1b, the laptop 10_1c, the TV 10_1d, and the desk monitor 10_1e also include a display module and an input module similarly to the smartphone 10_1a, and in some cases, may further include a communication module.

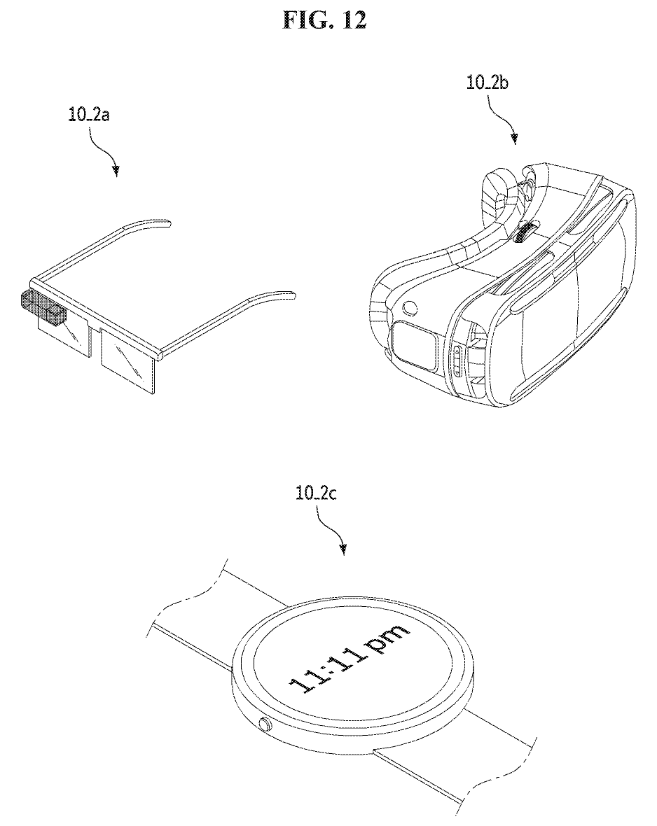

FIG. 12 illustrates an example in which an electronic device including a display module is applied to a wearable electronic device. The wearable electronic device may be a smart glasses 10_2a, a head mounted display 10_2b, a smart watch 10_2c, etc.

The smart glasses 10_2a and the head mounted display 10_2b may include a display module that emits a display image and a reflector that reflects the emitted display image and provides the reflected display image to the user's eyes, and may provide the user with a virtual reality or augmented reality screen through the display module and the reflector.

The smart watch 10_2c includes a biometric sensor as an input device and may provide the biometric information recognized by the biometric sensor to the user through the display module.

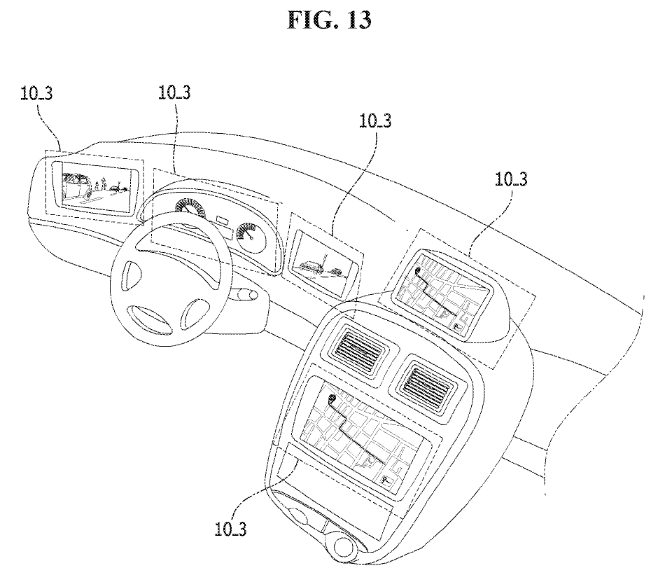

FIG. 13 illustrates an example in which an electronic device including a display module is applied to a vehicle. For example, an electronic device 10_3 may be applied to a dashboard, center fascia, etc. of an automobile, or may be applied to a Center Information Display (CID) located on the dashboard of the automobile or a room mirror display replacing a side mirror.

In concluding the detailed description, those skilled in the art will appreciate that many variations and modifications can be made to the disclosed embodiments without departing from the spirit and scope of embodiments according to the present disclosure. Therefore, the disclosed embodiments of the present disclosure are used in a generic and descriptive sense only and not for purposes of limitation.

What is claimed is:

1. A display device comprising:
a substrate including a display area and a non-display area;
a first electrode in a sub-pixel area of the display area;
a middle layer on the first electrode and defining a light emitting area of the first electrode;
a light emitting stack on the middle layer;
a second electrode on the light emitting stack; and
a Test Element Group (TEG) layer in a power connection area of the non-display area and including a same material as the light emitting stack.

2. The display device of claim 1, further comprising a power connection electrode in the power connection area,
wherein the second electrode extends to the power connection area and is connected to the power connection electrode.

3. The display device of claim 2, wherein the power connection electrode includes:
a first power connection electrode;
a second power connection electrode connected to the first power connection electrode on the first power connection electrode;
a buffer layer connected to the second power connection electrode on the second power connection electrode; and
a third power connection electrode connected to the buffer layer and the second electrode on the buffer layer.

4. The display device of claim 3, further comprising an auxiliary layer on the buffer layer,
wherein the third power connection electrode is on the auxiliary layer, and
the third power connection electrode is connected to the buffer layer through a first contact hole and a second contact hole penetrating through the auxiliary layer.

5. The display device of claim 4, wherein a size of the second contact hole is greater than a size of the first contact hole.

6. The display device of claim 5, wherein the TEG layer is on the third power connection electrode and overlaps the second contact hole.

7. The display device of claim 4, further comprising:
a barrier electrode between the substrate and the first electrode in the sub-pixel area;
a reflective electrode between the barrier electrode and the first electrode; and
a resonance control layer between the reflective electrode and the first electrode.

8. The display device of claim 7, wherein the first power connection electrode is at a same layer as the barrier electrode,
the second power connection electrode is at a same layer as the reflective electrode, and
the third power connection electrode is at a same layer as the first electrode.

9. The display device of claim 1, further comprising a bank layer on the middle layer,
wherein the light emitting stack is cut on the bank layer.

10. The display device of claim 9, wherein the bank layer has an undercut structure in the sub-pixel area, and
a non-undercut structure in the power connection area.

11. The display device of claim 9, wherein the bank layer includes:
a first bank; and
a second bank on the first bank.

12. The display device of claim 11, wherein in the sub-pixel area, the second bank includes a tip that does not overlap the first bank, and
in the power connection area, an edge of the second bank overlaps the first bank.

13. The display device of claim 2, wherein the middle layer includes:
a capping layer on the first electrode and the power connection electrode; and
a planarization layer on the capping layer.

14. The display device of claim 13, wherein the middle layer further includes a protective layer on the planarization layer.

15. An electronic device comprising:
a display device configured to display images,
wherein the display device includes:
a substrate including a display area and a non-display area;
a first electrode in a sub-pixel area of the display area;
a middle layer on the first electrode and defining a light emitting area of the first electrode;
a light emitting stack on the middle layer;
a second electrode on the light emitting stack; and
a Test Element Group (TEG) layer in a power connection area of the non-display area and including a same material as the light emitting stack.

16. The electronic device of claim 15, wherein the display device has a resolution of 4,000 pixels per inch (PPI) or higher.

17. The electronic device of claim 15, wherein the display device includes an active area at which the images are displayed and a non-active area outside the active area at which the images are not displayed, and
a maximum width of the active area is 1.5 inches or less.

18. The electronic device of claim 15, wherein the electronic device is one of a smartphone, a tablet, a laptop, a TV, a desk monitor, a smart glasses, a smart watch, a head mounted display, or a vehicle.

19. The electronic device of claim 15, further comprising a power connection electrode in the power connection area,
wherein the second electrode extends to the power connection area and is connected to the power connection electrode.

20. The electronic device of claim 19, wherein the power connection electrode includes:
a first power connection electrode;
a second power connection electrode connected to the first power connection electrode on the first power connection electrode;
a buffer layer connected to the second power connection electrode on the second power connection electrode; and
a third power connection electrode connected to the buffer layer and the second electrode on the buffer layer.
